(19) United States
(12) Patent Application Publication
(10) Pub. No.: US 2026/0090062 A1
(43) Pub. Date: Mar. 26, 2026

(54) NITRIDE-BASED SEMICONDUCTOR DEVICE AND METHOD FOR MANUFACTURING THEREOF

(71) Applicant: INNOSCIENCE (SUZHOU) SEMICONDUCTOR CO., LTD., Suzhou, Jiangsu (CN)

(72) Inventors: Zhongyu ZHANG, Suzhou, Jiangsu (CN); Kai HU, Suzhou, Jiangsu (CN); Huixin HE, Suzhou, Jiangsu (CN); Haibo GUO, Suzhou, Jiangsu (CN)

(73) Assignee: INNOSCIENCE (SUZHOU) SEMICONDUCTOR CO., LTD., Suzhou, Jiangsu (CN)

(21) Appl. No.: 19/111,410

(22) PCT Filed: Sep. 27, 2022
(86) PCT No.: PCT/CN2022/121553

§ 371 Date: Mar. 13, 2025

(51) Int. Cl. H10D 64/27; H01L 23/31; H10D 30/01; H10D 30/47; H10D 62/85

(52) U.S. Cl. CPC H10D 64/518; H10D 30/015; H10D 30/475; H10D 62/8503; H10W 74/137

(57) ABSTRACT

A nitride-based semiconductor device includes a first III-V nitride-based semiconductor layer, a second III-V nitride-based semiconductor layer, a gate dielectric layer, and a gate electrode. The second III-V nitride-based semiconductor layer is disposed over the first III-V nitride-based semiconductor layer and has a bandgap higher than a bandgap of the first III-V nitride-based semiconductor layer. The gate dielectric layer is disposed over the second III-V nitride-based semiconductor layer. The gate electrode is disposed over the gate dielectric layer and includes a first portion and a first portion. The first portion makes contact with the gate dielectric layer and has a rounded corner.

### CROSS-REFERENCE TO RELATED APPLICATIONS

This application is a national stage of international PCT application No. PCT/CN2022/121553 filed on Sep. 27, 2022, the entire contents of which are incorporated herein by reference.

### FIELD

The present disclosure generally relates to a nitride-based semiconductor device. More specifically, the present disclosure relates to a nitride-based semiconductor device having a gate electrode with a curved profile.

### BACKGROUND

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY

In accordance with one aspect of the present disclosure, a nitride-based semiconductor device is provided. The nitride-based semiconductor device includes a first III-V nitride-based semiconductor layer, a second III-V nitride-based semiconductor layer, a gate dielectric layer, and a gate electrode. The second III-V nitride-based semiconductor layer is disposed over the first III-V nitride-based semiconductor layer and has a bandgap higher than a bandgap of the first III-V nitride-based semiconductor layer. The gate dielectric layer is disposed over the second III-V nitride-based semiconductor layer. The gate electrode is disposed over the gate dielectric layer and includes a first portion and a first portion. The first portion makes contact with the gate dielectric layer and has a rounded corner. The second portion is located on the first portion and is wider than the first portion.

In accordance with one aspect of the present disclosure, a method for manufacturing a nitride-based semiconductor device is provided. The method has steps as follows; forming a first III-V nitride-based semiconductor layer over a substrate; forming a second III-V nitride-based semiconductor layer over the first III-V nitride-based semiconductor layer; forming a gate dielectric layer over the second III-V nitride-based semiconductor layer; forming a passivation layer over the gate dielectric layer; forming a recess in the passivation layer; performing an etching process with respect to the recess, such that the gate dielectric layer is exposed; forming a gate electrode in the passivation layer to make contact with the gate dielectric layer.

In accordance with one aspect of the present disclosure, a nitride-based semiconductor device is provided. The nitride-based semiconductor device includes a first III-V nitride-based semiconductor layer, a second III-V nitride-based semiconductor layer, a gate dielectric layer, a gate electrode. The second III-V nitride-based semiconductor layer is disposed over the first III-V nitride-based semiconductor layer and has a bandgap higher than a bandgap of the first III-V nitride-based semiconductor layer. The gate dielectric layer is disposed over the second III-V nitride-based semiconductor layer. The gate electrode is disposed over the gate dielectric layer and having a waved sidewall.

By the above configuration, the gate electrode can have different widths so is able to function as a multiple field plates configuration. The transition connection between different field plates is “gradually”, which is achieved by the curve/wave profile. It results in the gradual modulation to the electrical field distribution correspondingly.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1 is a vertical cross-sectional view of a nitride-based semiconductor device according to some embodiments of the present disclosure.

FIG. 2A, FIG. 2B, FIG. 2C, FIG. 2D, and FIG. 2E show different stages of a method for manufacturing a nitride-based semiconductor device according to some embodiments of the present disclosure;

FIG. 3 is a vertical cross-sectional view of a nitride-based semiconductor device according to some embodiments of the present disclosure;

FIG. 4 is a vertical cross-sectional view of a nitride-based semiconductor device according to some embodiments of the present disclosure; and

FIG. 5 is a vertical cross-sectional view of a nitride-based semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

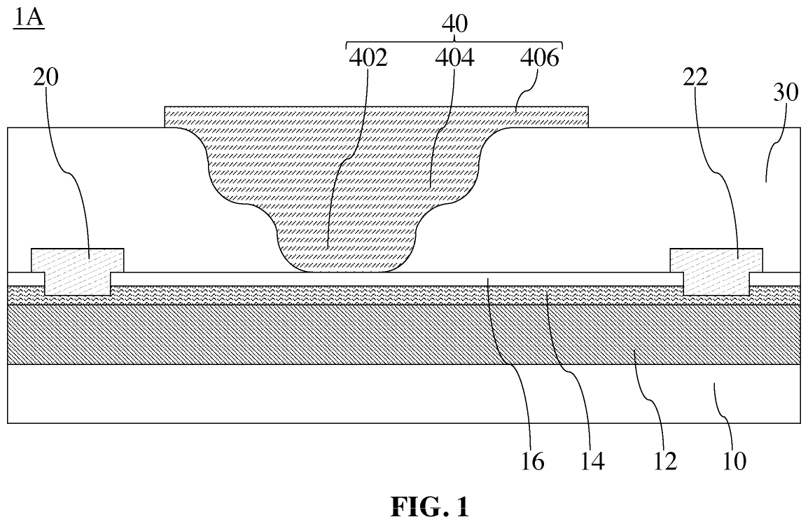

FIG. 1 is a vertical cross-sectional view of a nitride-based semiconductor device 1A according to some embodiments of the present disclosure. The nitride-based semiconductor device 1A includes a substrate 10, nitride-based semiconductor layers 12, 14, a gate dielectric layer 16, electrodes 20 and 22, a passivation layer 30, and a gate electrode 40.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

In some embodiments, the nitride-based semiconductor device 1A may further include a buffer layer (not illustrated). The buffer layer is disposed between the substrate 10 and the nitride-based semiconductor layer 12. The buffer layer can be configured to reduce lattice and thermal mismatches between the substrate 10 and the nitride-based semiconductor layer 12, thereby curing defects due to the mismatches/difference. The buffer layer may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AIN, AlGaN, InAlGaN, or combinations thereof.

In some embodiments, the semiconductor device 1A may further include a nucleation layer (not shown). The nucleation layer may be formed between the substrate 10 and a buffer layer. The nucleation layer can be configured to provide a transition to accommodate a mismatch/difference between the substrate 10 and a III-nitride layer of the buffer layer. The exemplary material of the nucleation layer can include, for example but is not limited to AIN or any of its alloys.

The nitride-based semiconductor layer 12 can be disposed on/over/above the buffer layer. The nitride-based semiconductor layer 14 can be disposed on/over/above the nitride-based semiconductor layer 12. The exemplary materials of the nitride-based semiconductor layer 12 can include, for example but are not limited to, nitrides or group III-V compounds, such as GaN, AlN, InN, InₓAl_{y}Ga_{(1-x-y)}N where x+y≤1, AlₓGa_{(1-y)}N where x≤1. The exemplary materials of the nitride-based semiconductor layer 14 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1. In some embodiments, the nitride-based semiconductor layers 12 and 14 are selected as III-V nitride-based semiconductor layers.

The exemplary materials of the nitride-based semiconductor layers 12 and 14 are selected such that the nitride-based semiconductor layer 14 has a bandgap (i.e., forbidden band width) greater/higher than a bandgap of the nitride-based semiconductor layer 12, which causes electron affinities thereof different from each other and forms a heterojunction therebetween. For example, when the nitride-based semiconductor layer 12 is an undoped GaN layer having a bandgap of approximately 3.4 eV, the nitride-based semiconductor layer 14 can be selected as an AlGaN layer having bandgap of approximately 4.0 eV. As such, the nitride-based semiconductor layers 12 and 14 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 1A is available to include at least one GaN-based high-electron-mobility transistor (HEMT).

The gate dielectric layer 16 is disposed over the III-V nitride-based semiconductor layer 14. In some embodiments, the material of the gate dielectric layer 16 can include, for example but is not limited to, dielectric materials. For example, the gate dielectric layer 16 can include SiNx, SiOx, SiON, SiC, SiBN, SiCBN, oxides, nitrides, plasma enhanced oxide (PEOX), or combinations thereof.

The electrodes 20 and 22 are disposed on the nitride-based semiconductor layer 14 and the gate dielectric layer 16. The electrode 20 can penetrate the gate dielectric layer 16 to make contact with the nitride-based semiconductor layer 14. The electrode 22 can penetrate the gate dielectric layer 16 to make contact with the nitride-based semiconductor layer 14. Each of the electrodes 20 and 22 can serve as a source electrode or a drain electrode. In some embodiments, the electrodes 20 and 22 can be called ohmic electrodes.

In some embodiments, the electrodes 20 and 22 can include, for example but are not limited to, metals, alloys, doped semiconductor materials (such as doped crystalline silicon), compounds such as silicides and nitrides, other conductor materials, or combinations thereof. The exemplary materials of the electrodes 20 and 22 can include, for example but are not limited to, Ti, AlSi, TiN, or combinations thereof. The electrodes 20 and 22 may be a single layer, or plural layers of the same or different composition. In some embodiments, the electrodes 20 and 22 can form ohmic contact with the nitride-based semiconductor layer 14. The ohmic contact can be achieved by applying Ti, Al, or other suitable materials to the electrodes 20 and 22.

In some embodiments, each of the electrodes 20 and 22 is formed by at least one conformal layer and a conductive filling. The conformal layer can wrap the conductive filling. The exemplary materials of the conformal layer can include, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

The passivation layer 30 is disposed over the gate dielectric layer 16. The passivation layer 30 covers the gate dielectric layer 16 and the electrodes 20 and 22. The passivation layer 30 and the gate dielectric layer 16 can form an interface therebetween. In some embodiments, the material of the passivation layer 30 can include, for example but is not limited to, dielectric materials. For example, the passivation layer 30 can include SiNx, SiOx, SiON, SiC, SiBN, SiCBN, oxides, nitrides, plasma enhanced oxide (PEOX), or combinations thereof. In some embodiments, the passivation layer 30 and the gate dielectric layer 16 can have different materials. The reason for the different materials as selected for the passivation layer 30 and the gate dielectric layer 16 is to make the gate dielectric layer 16 serve as an etch stop layer at an etching stage of the passivation layer 30.

The gate electrode 40 is disposed over the gate dielectric layer 16. The gate electrode 40 can penetrate the passivation layer 30 to make contact with the gate dielectric layer 16. The gate electrode 40 can form an interface with inner sidewalls of the passivation layer 30. The gate electrode 40 may have a top surface higher than the passivation layer 30. The gate electrode 40 is located between the electrodes 20 and 22.

The gate electrode 40 includes portions 402, 404, 406. The gate electrode 40 can have a width increasing along an upward direction.

The portion 402 makes contact with the gate dielectric layer 16. In some embodiments, an interface between the gate dielectric layer 16 and the portion 402 is substantially flat. The portion 402 has rounded corners at sidewalls thereof. The portion 402 has a width greater than a contact width between the gate electrode 40 and the gate dielectric layer 16.

The portion 404 is located on the portion 402. The portion 404 is connected to the portion 402. The portion 404 is wider than the portion 402. The portion 404 has rounded corners at sidewalls thereof. The connection between the portions 402 and 404 is in a rounded profile. For example, the rounded profile can be achieved by a concave receiving the passivation layer 30.

The portion 406 is located on the portion 404. The portion 406 is connected to the portion 404. The portion 406 is wider than the portion 404. The connection between the portions 404 and 406 is in a rounded profile. For example, the rounded profile can be achieved by a concave receiving the passivation layer 30.

In some embodiments, the portions 402, 404, 406 can collectively form curved sidewalls for the gate electrode 40. The passivation layer 30 can form a curved interface with the gate electrode 40. A vertical distance from the gate dielectric layer 16 to the curved sidewalls of the gate electrode 40 can gradually increase. In some embodiments, the portions 402, 404, 406 can collectively form waved sidewalls for the gate electrode 40. The passivation layer 30 can form a waved interface with the gate electrode 40. A vertical distance from the gate dielectric layer 16 to the waved sidewalls of the gate electrode 40 can gradually increase. That is, the increase rate in the distance is not constant substantially. The passivation layer 30 has the inner sidewalls with an inconstant slope, including irregularly inclining. The degree of inclination of the inner sidewalls of the passivation layer 30 may increase, decrease, and then increase.

Such the configuration is to make the modulation to the electrical field distribution smooth. More specifically, the gate electrode 40 having different widths is able to function as a multiple field plates configuration. For example, ends of the portion 402 which are separated from the gate dielectric layer 16 can serve as a field plate. Similarly, ends of the portion 404 which are out of the portion 402 can serve as a field plate. The transition connection between different field plates is “gradually”, which is achieved by the curve/wave profile. It results in the gradual modulation to the electrical field distribution correspondingly. In the view of modulation to the electrical field distribution, sharped profile may result in suddenly changing which tends to form electrical field distribution having peak. However, the gate electrode 40 of the present disclosure can provide well stable modulation to the electrical field distribution.

The gate electrode 40 may be formed as a single layer, or plural layers of the same or different compositions, and may be made of metals or metal compounds. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

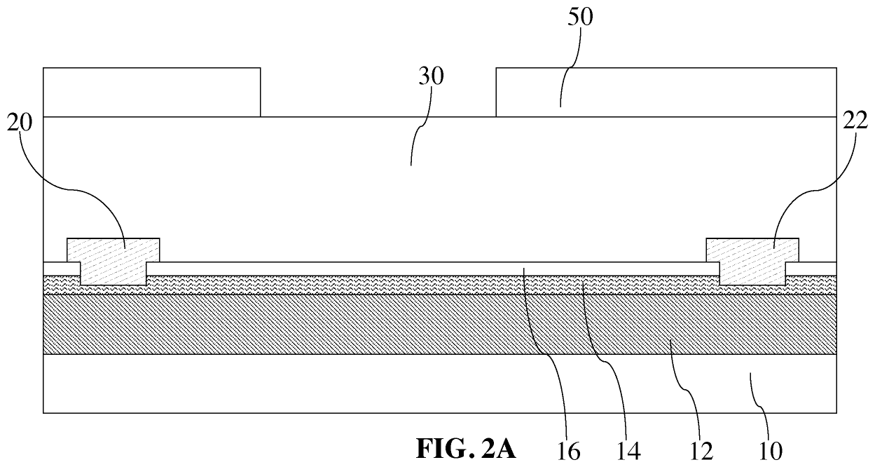

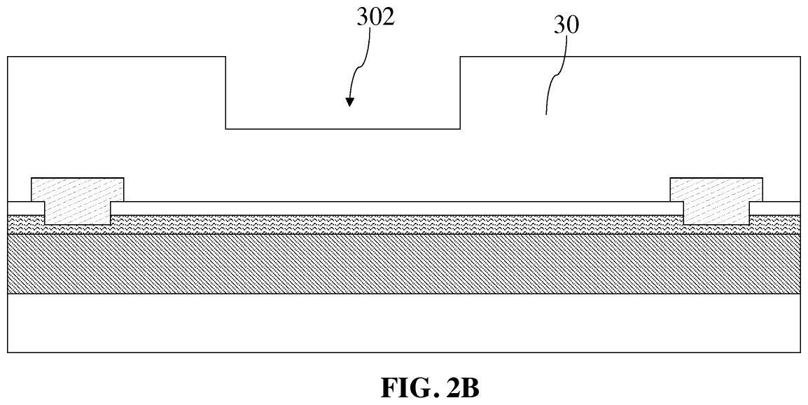

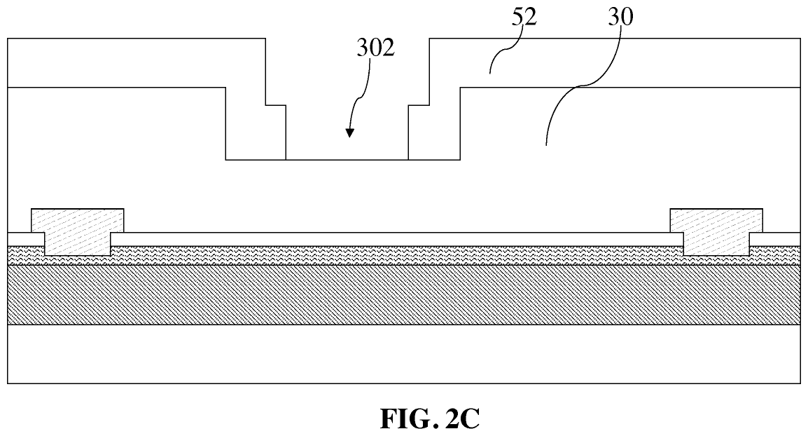

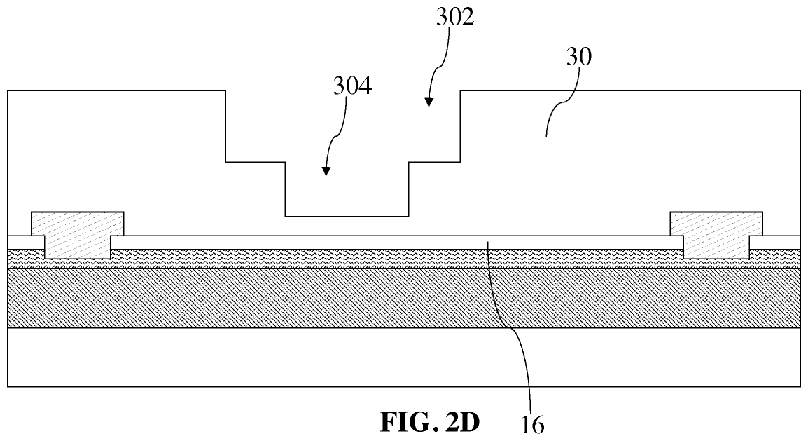

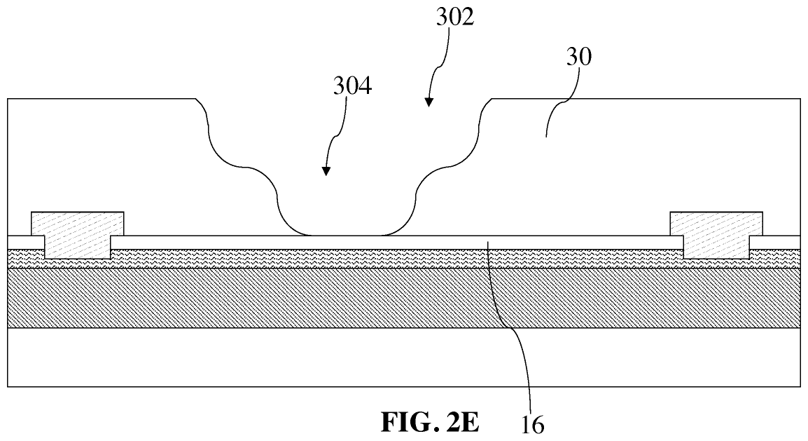

The structure as shown in FIG. 1 can be achieved by a series of processes with the nitride-based semiconductor layer 14 protected from etching stages. Different stages of a method for manufacturing the semiconductor device 1A are shown in FIG. 2A, FIG. 2B, FIG. 2C, FIG. 2D, and FIG. 2E, as described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a substrate 10 is provided. A nitride-based semiconductor layer 12 is formed on the substrate 10. A nitride-based semiconductor layer 14 is formed on the nitride-based semiconductor layer 12. A gate dielectric layer 16 is formed on the nitride-based semiconductor layer 14. Electrodes 20 and 22 are formed on the nitride-based semiconductor layer 14. A passivation layer 30 is formed on the gate dielectric layer 16. The passivation layer 30 covers the electrodes 20 and 22. A mask layer 50 is formed on the passivation layer 30. The mask layer 50 has an opening to expose a portion of the passivation layer 30.

Referring to FIG. 2B, a portion of the passivation layer 30 is removed. In some embodiments, the removal of the passivation layer 30 is performed by an etching stage using the mask layer 50. After the removal of the passivation layer 30, a recess 302 is formed in the passivation layer 30.

Referring to FIG. 2C, a mask layer 52 is formed on the passivation layer 30. The mask layer 52 can extend into the recess 302 of the passivation layer 30. The mask layer 52 has an opening in the recess 302 to expose a portion of the passivation layer 30.

Referring to FIG. 2D, a portion of the passivation layer 30 is removed. In some embodiments, the removal of the passivation layer 30 is performed by an etching stage using the mask layer 52. After the removal of the passivation layer 30, a further recess 304 is formed in the passivation layer 30. The recess 304 communicates with the recess 302 and is narrower than the recess 302. At this stage, no portion of the gate dielectric layer 16 is exposed.

Referring to FIG. 2E, an etching process is performed with respect to the recesses 302 and 304 of the passivation layer 30, such that a portion of the gate dielectric layer 16 is exposed. The present etching stage is a mask-free process. In some embodiments, the present etching stage is achieved by using a dry etching. During the dry etching, right-angle corners of passivation layer 30 are etched greatly than other portions. The right-angle corners may become curved corners. As such, the passivation layer 30 can have curved or waved inner sidewalls after the etching process. Furthermore, the thickness of the passivation layer 30 may reduce. Thereafter, a gate electrode is formed in the recesses 302 and 304 of the passivation layer 30 to make contact with the gate dielectric layer 16, in which the gate electrode can form an interface with the inner sidewalls of the passivation layer 30.

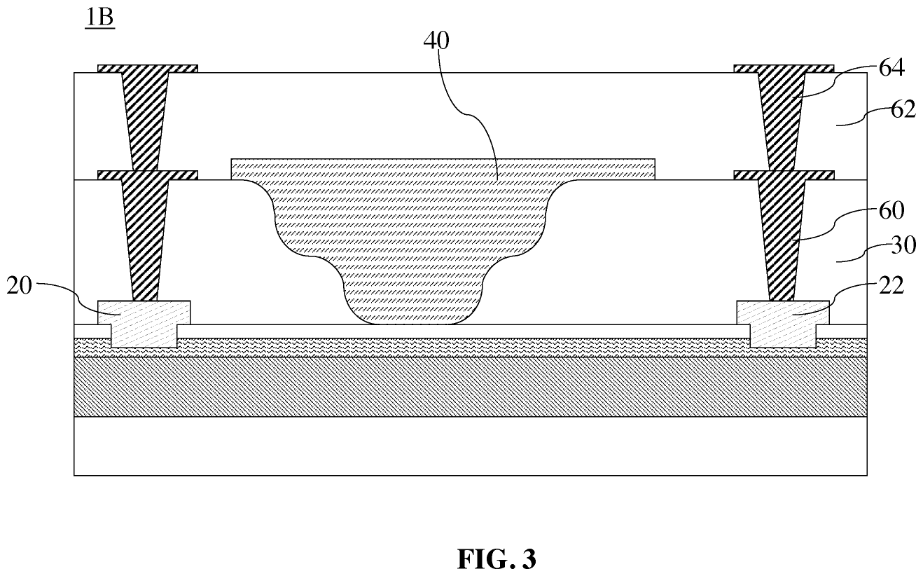

FIG. 3 is a vertical cross-sectional view of a nitride-based semiconductor device 1B according to some embodiments of the present disclosure. The nitride-based semiconductor device 1B is similar to the semiconductor device 1A as described and illustrated with reference to FIG. 1, except that the nitride-based semiconductor device 1B further includes contact vias 60, 64, and a passivation 62.

The contact vias 60 are disposed over the electrodes 20 and 22. The contact vias 60 are disposed within the passivation layer 30. The contact vias 60 can penetrate the passivation layer 30. The contact vias 60 can extend longitudinally to connect to the electrodes 20 and 22. The exemplary materials of the contact vias 60 can include, for example but are not limited to, conductive materials, such as metals or alloys. The passivation layer 62 is disposed over the passivation layer 30. The passivation layer 62 covers the gate electrode 40. The passivation layer 62 can have the identical or the similar materials as the passivation layer 30. The contact vias 64 are disposed over the contact vias 60. The contact vias 64 are disposed within the passivation layer 62. The contact vias 64 can penetrate the passivation layer 62. The contact vias 64 can extend longitudinally to connect to the contact vias 60. The exemplary materials of the contact vias 64 can include, for example but are not limited to, conductive materials, such as metals or alloys.

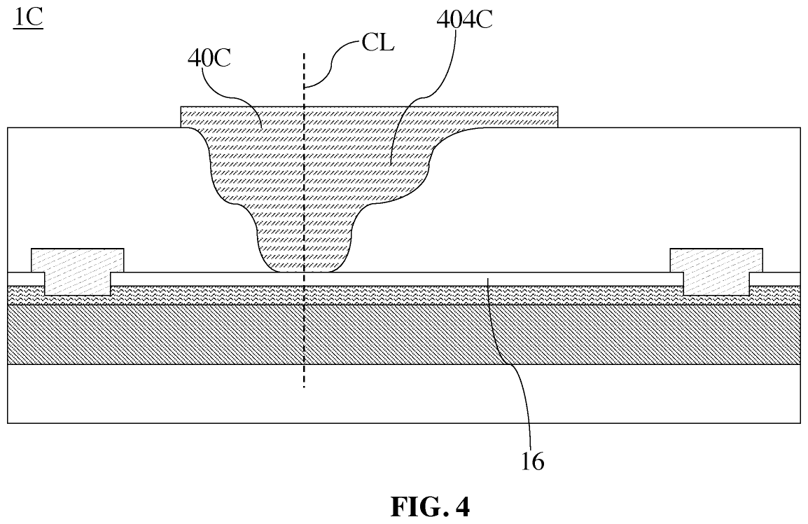

FIG. 4 is a vertical cross-sectional view of a nitride-based semiconductor device 1C according to some embodiments of the present disclosure. The nitride-based semiconductor device 1C is similar to the semiconductor device 1A as described and illustrated with reference to FIG. 1, except that the gate electrode 40 is replaced by a gate electrode 40C. The gate electrode 40C has an asymmetrically curved/waved profile with respect to a center line CL. The center line CL is at an exact center of an interface between the gate electrode 40C and the gate dielectric layer 16. The curved/waved profile of the gate electrode 40C is asymmetrical about the center line CL. More specifically, the portion 404C is asymmetrical about the center line CL, which has a right part longer than a left part. In some embodiments, such the design is to fit high voltage requirement.

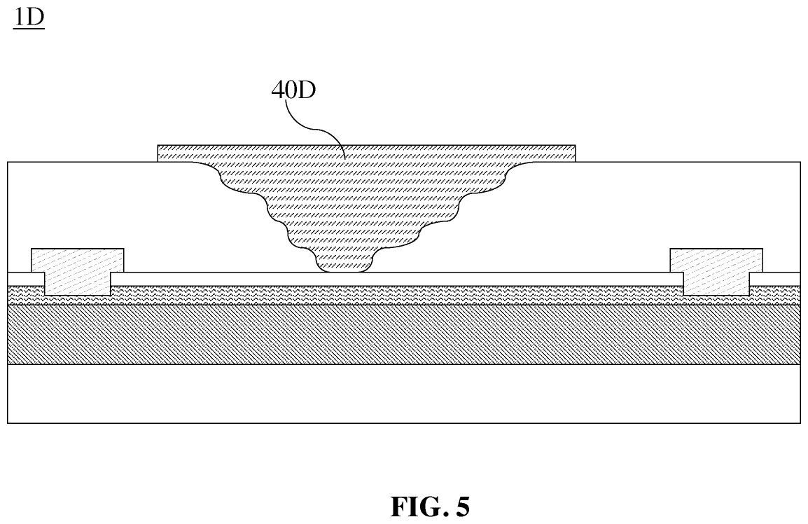

FIG. 5 is a vertical cross-sectional view of a nitride-based semiconductor device 1C according to some embodiments of the present disclosure. The nitride-based semiconductor device 1D is similar to the semiconductor device 1C as described and illustrated with reference to FIG. 4, except that the gate electrode 40D is replaced by a gate electrode 40D. The gate electrode 40D has an asymmetrically curved/waved profile as afore described. The gate electrode 40D has more portions to equivalently serve as multiple field plates. These field plates have rounded corners so the modulation to the electrical field distribution can get smoother.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to +5%, less than or equal to +4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device comprising:
a first III-V nitride-based semiconductor layer;
a second III-V nitride-based semiconductor layer disposed over the first III-V nitride-based semiconductor layer and having a bandgap higher than a bandgap of the first III-V nitride-based semiconductor layer;
a gate dielectric layer disposed over the second III-V nitride-based semiconductor layer; and
a gate electrode disposed over the gate dielectric layer and comprising:
a first portion making contact with the gate dielectric layer and having a rounded corner; and
a second portion located on the first portion and wider than the first portion.

2. The nitride-based semiconductor device of preceding claimsclaim 1, wherein the second portion has a rounded corner.

3. The nitride-based semiconductor device of claim 1, wherein connection between the first portion and the second portion is in a rounded profile.

4. The nitride-based semiconductor device of claim 1, wherein the first portion has a width greater than a contact width between the gate electrode and the gate dielectric layer.

5. The nitride-based semiconductor device of claim 1, wherein the first portion and the second portion collectively form a curved sidewall.

6. The nitride-based semiconductor device of claim 5, wherein a vertical distance from the gate dielectric layer to the curved sidewall gradually increases.

7. The nitride-based semiconductor device of claim 1, wherein the first portion and the second portion collectively form a waved sidewall.

8. The nitride-based semiconductor device of claim 7, wherein a vertical distance from the gate dielectric layer to the waved sidewall gradually increases.

9. The nitride-based semiconductor device of preceding claim 1, further comprising:
a passivation layer disposed over the gate dielectric layer, wherein the gate electrode penetrates the passivation layer.

10. The nitride-based semiconductor device of any one of claim 9, wherein the passivation layer forms a curved interface with the gate electrode.

11. The nitride-based semiconductor device of claim 9, wherein the passivation layer forms a waved interface with the gate electrode.

12. The nitride-based semiconductor device of claim 9, wherein the passivation layer has an inner sidewall with an inconstant slope.

13. The nitride-based semiconductor device of claim 12, wherein a degree of inclination of the inner sidewall of the passivation layer increases, decreases, and then increases.

14. The nitride-based semiconductor device of any one of claim 1, wherein the gate electrode has an asymmetric profile.

15. The nitride-based semiconductor device of claim 1, further comprising a source electrode and a drain electrode disposed over the second III-V nitride-based semiconductor layer, wherein the gate electrode is located between the source electrode and the drain electrode.

16. A method for manufacturing a nitride-based semiconductor device, comprising:
forming a first III-V nitride-based semiconductor layer over a substrate;
forming a second III-V nitride-based semiconductor layer over the first III-V nitride-based semiconductor layer;
forming a gate dielectric layer over the second III-V nitride-based semiconductor layer;
forming a passivation layer over the gate dielectric layer;
forming a recess in the passivation layer;
performing an etching process with respect to the recess, such that the gate dielectric layer is exposed; and
forming a gate electrode in the passivation layer to make contact with the gate dielectric layer.

17. The method of claim 16, wherein the passivation layer has a waved inner sidewall after the etching process.

18. The method of claim 17, wherein the gate electrode forms an interface with the waved inner sidewall of the passivation layer.

19. The method of claim 16, wherein an entirety of the gate dielectric layer is covered by the passivation layer, and/or the gate dielectric layer and the passivation layer have different materials.

20. (canceled)

21. A nitride-based semiconductor device comprising:
a first III-V nitride-based semiconductor layer;
a second III-V nitride-based semiconductor layer disposed over the first III-V nitride-based semiconductor layer and having a bandgap higher than a bandgap of the first III-V nitride-based semiconductor layer;
a gate dielectric layer disposed over the second III-V nitride-based semiconductor layer; and
a gate electrode disposed over the gate dielectric layer and having a waved sidewall.

22-25. (canceled)
